(19) United States
(12) Patent Application Publication
(10) Pub. No.: US 2008/0146001 A1
(43) Pub. Date: Jun. 19, 2008

(54) Pre-STI nitride descum step for increased margin against STI seam voids

(75) Inventors: Cody Michael Berger, Mckinney, TX (US); Brian Douglas Reid, Plano, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/639,934

(22) Filed: Dec. 15, 2006

(51) Int. Cl. H01L 21/762

(52) U.S. Cl. 438/424; 257/E21.546

(57) ABSTRACT

A method of forming a shallow trench isolation structure is provided, and includes forming a mask structure over active regions of a substrate, thereby defining a trench region therebetween. A descum is then performed to remove any particulate matter that may be in the trench region over the substrate. A trench is then formed in the substrate corresponding to the trench region of the mask structure, followed by a filling of the trench with an electrically insulating material.

### FIELD OF INVENTION

The present invention relates generally to semiconductor devices, and more particularly relates to the formation of shallow trench isolation (STI) structures in semiconductor processing.

### BACKGROUND OF THE INVENTION

Integrated circuits are fabricated by forming electrical devices on or in a semiconductor substrate and interconnecting these devices to form electrical circuits. In the design and manufacture of such semiconductor devices, it is necessary to isolate the individual electrical devices from one another, for example, to avoid parasitic transistor operation in adjacent MOSFET devices. A variety of techniques have been developed for electrically isolating devices in integrated circuit fabrication. One such technique is known as local oxidation of silicon (LOCOS), which involves selectively growing oxide in non-active or field regions of a substrate using a nitride mask overlying active regions thereof. As device geometries have been reduced beyond submicron sizes, conventional LOCOS isolation technologies have become ineffective or at least less popular, due to bird's beak issues and other shortcomings. Accordingly alternate isolation processes for CMOS and bipolar technologies have been developed for semiconductor devices such as logic and/or memory.

One alternative technique for isolation processing includes shallow trench isolation (STI), in which isolation trenches are provided substantially vertically into the substrate, which are then filled with electrically isolating materials such as an insulative dielectric (e.g., silicon oxide, SiO₂). The resulting isolation structures separate and provide electrical isolation between active areas that may contain electric devices such as transistors and/or memory cells subsequently formed on either side of the trench.

Referring to FIGS. 1A-1G, one exemplary conventional STI formation process of a semiconductor wafer 2 is illustrated. Beginning in FIG. 1A, a thermal oxidation process is provided to grow a barrier or pad oxide layer 4 having a thickness 4′ of about 100-200 Angstroms over a semiconductor substrate 6. A nitride layer 8 (e.g., Si₃N₄) is then deposited in FIG. 1B, such as by low pressure chemical vapor deposition (LPCVD). The nitride layer 8 is used to protect the active regions of the substrate 6 from adverse effects of the subsequent formation of isolation trenches between the active regions. In addition, the nitride layer thickness is set so as to allow process control margin for the subsequent planarization of the dielectric material following trench fill. Thus, in one example the conventional nitride layer 8 is deposited to a thickness 8′ of about 2,000 Angstroms. The active regions of the device 2 are then masked in FIG. 1C using a patterned etch mask 10, leaving the isolation region of the nitride layer 8 exposed.

Thereafter an etch process 12 is employed to etch through the nitride layer 8, the barrier oxide 4, and into the substrate 6 to form a trench 14 in the exposed isolation region. As illustrated in FIG. 1D, the active region etch mask 10 is removed and a liner 16 is formed in the trench 14, such as through thermal oxidation of the exposed portions of the trench 14, in order to remove damage from the silicon etch process 12. SiO₂ or other electrically insulating dielectric fill material 18 is then deposited in FIG. 1E via a deposition process 20 that fills the trench 14 and also covers the nitride layer 8 in the active substrate regions. A chemical mechanical polishing (CMP) or other type planarization process 22 is then employed in FIG. 1F, to planarize the wafer surface, which exposes the upper surface of the nitride layer 8. Following planarization, the nitride layer 8 is then removed via an etch process 24 in FIG. 1G, leaving a step between the barrier oxide 4 and the top of the remaining trench fill material 18 having a step height 26 generally equal to the post-CMP thickness 8′ of the removed nitride layer 8.

While the above STI formation process is sufficient for many applications, it is always desirable to make further improvements in such processes.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The invention relates to semiconductor devices and fabrication methods. According to one aspect of the invention, a method of forming a shallow trench isolation structure is provided. The method comprises forming a mask structure over active regions of a substrate, wherein the active regions define a trench region therebetween. A descum operation is performed to remove any particulate matter from the trench region over the substrate. A trench is then formed in the substrate that corresponds to the trench region of the mask structure. The trench is later filled with an electrically insulating material.

According to another aspect of the invention, a method of forming a shallow trench isolation structure comprises forming a base buffer layer over the substrate. A mask layer is then formed over the base buffer layer, and is patterned to form an opening therein that defines a trench region. A descum operation is performed to remove any particulate matter in the mask layer opening. The base buffer layer and the substrate are then patterned through the mask layer opening to form a trench in the substrate. The trench is later filled with an electrically insulating material.

According to still another aspect of the invention, a method of forming a shallow trench isolation structure comprises forming a patterned etch mask over the substrate, wherein the patterned etch mask defines a trench opening. A descum operation is then performed after forming the patterned etch mask to remove any particulate matter from the trench opening. A trench is then formed corresponding to the trench opening in the substrate, and the trench is filled with an electrically insulating material.

In yet another aspect of the invention, a descum operation comprises subjecting the device to an etchant such as an oxygen based plasma. In one embodiment, the substrate is biased, wherein oxygen ions in the oxygen plasma are directed down toward the substrate in a generally vertical manner, wherein the descumming takes place primarily in the trench opening portion of the device.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIGS. 1A-1G are partial side elevation views in section illustrating a conventional shallow trench isolation process for providing isolation between adjacent electrical devices in an upper portion of a semiconductor wafer;

FIGS. 2A-2E are partial side elevation views in section illustrating a conventional shallow trench isolation process and a problem associated therewith that was identified by the inventors of the present invention;

FIG. 3 is a flow chart diagram illustrating a method of forming a shallow trench isolation structure according to one embodiment of the invention; and

FIGS. 4A-4I are partial side elevation views in section illustrating a shallow trench isolation process for providing isolation between adjacent electrical devices in a semiconductor body according to an embodiment of the invention.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale. The invention is directed to a method of forming a shallow trench isolation structure that overcomes the shortcomings in the prior art.

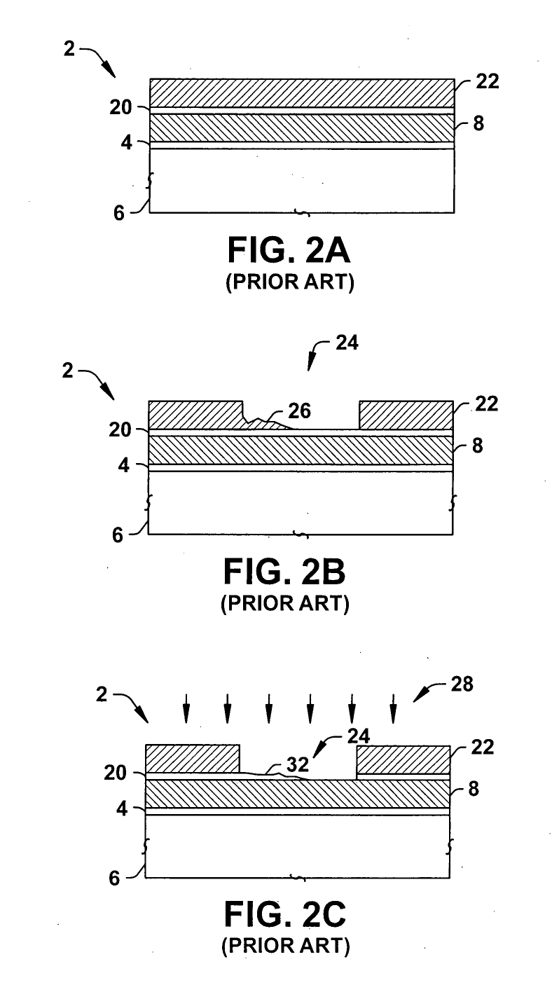

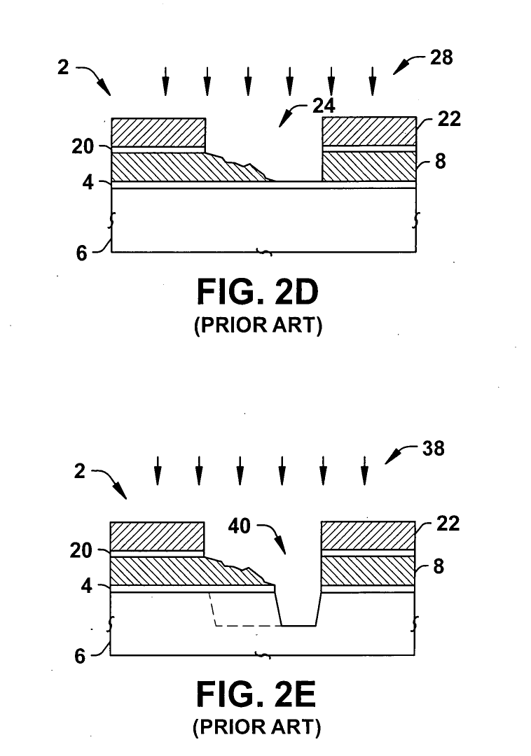

In order to appreciate various aspects of the present invention, a brief description of a conventional shallow trench isolation process will be described in conjunction with FIGS. 2A-2E, and a problem associated therewith that was identified by the inventors of the present invention.

FIG. 2A shows a semiconductor device 2 comprising a semiconductor body 6 with a pad oxide 4 and nitride layer 8 formed thereover. Overlying the nitride layer 8 is an anti-reflective coating 20 and a photoresist layer 22. As is generally known and appreciated by those of ordinary skill in the art, the anti-reflective coating 20 serves to reduce an amount of reflection of radiation during an exposure of the photoresist 22. The reduced reflection substantially prevents a standing wave phenomena from negatively impacting the critical dimension of the developed photoresist. After exposure, the photoresist layer 22 is developed, wherein the exposed portion of the photoresist is removed, the exposed portion corresponding to a trench region 24, as illustrated in FIG. 2B.

However, as further illustrated in FIG. 2B, as the critical dimensions of the trench opening 24 continues to shrink, the inventors of the present invention identified a problem that particulate matter such as a portion of unremoved photoresist 26 sometimes remains in the opening. As will be appreciated, the unwanted material in some cases can contribute to STI seam voiding. For example, as illustrated in FIG. 2C, after development of the photoresist layer 22, the anti-reflective coating 20 is removed via an etch process 28. However, as illustrated in FIG. 2C, the previously unremoved contaminant or portion 26 of photoresist in the trench opening 24 may cause a portion 32 of the anti-reflective coating 20 to not be fully removed.

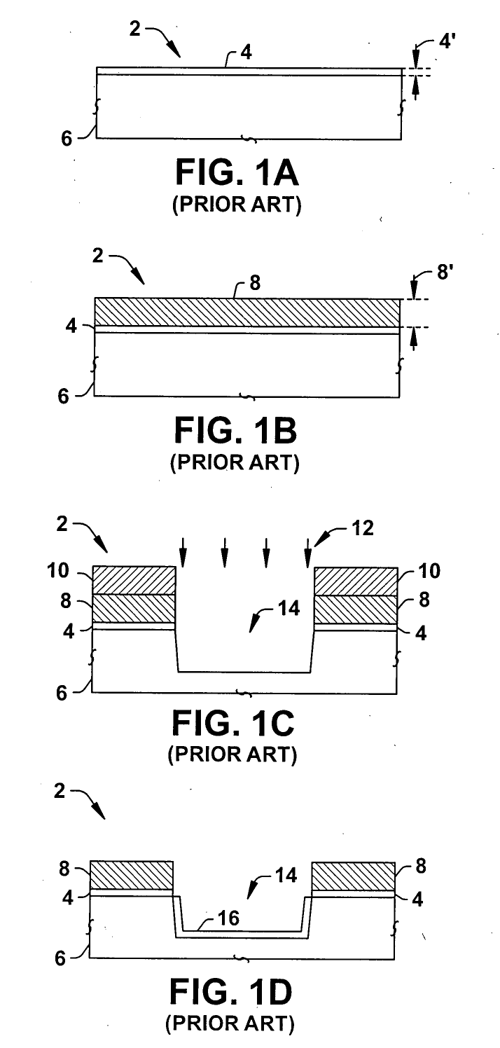

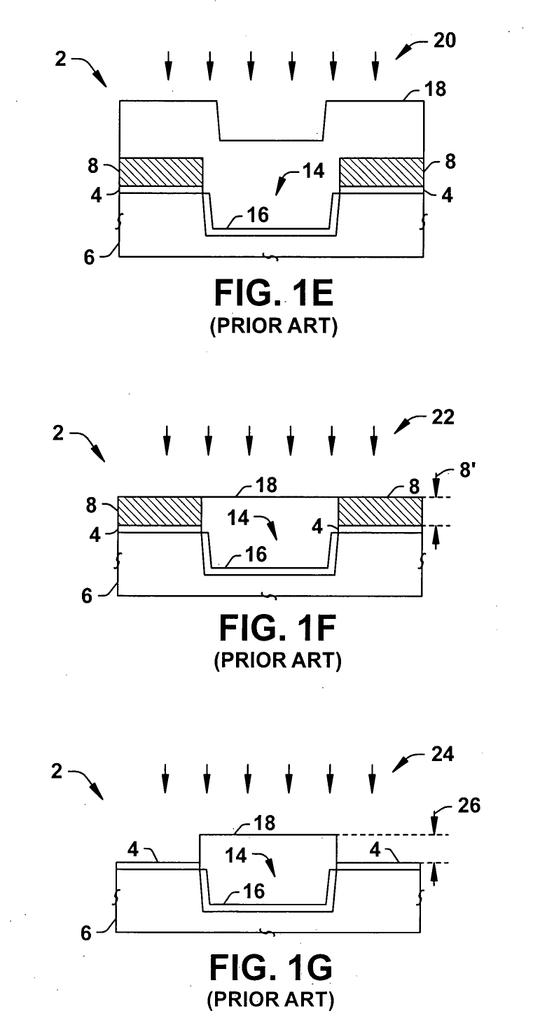

As further illustrated in FIGS. 2D and 2E, an unetched region corresponding to the original contaminant 26 may get transferred down to each succeeding underlying layer during the subsequent etches, such that during a final trench etch 38, an STI seam void 40 exists. Consequently, the full trench, for example, as illustrated in FIG. 1C does not get formed. This problem may then lead to failures or performance degradation due to the improperly formed resultant STI structures. Because the inventors of the present invention discovered this failure mechanism, the present invention is directed to an STI isolation process that overcomes the shortcomings of the prior art.

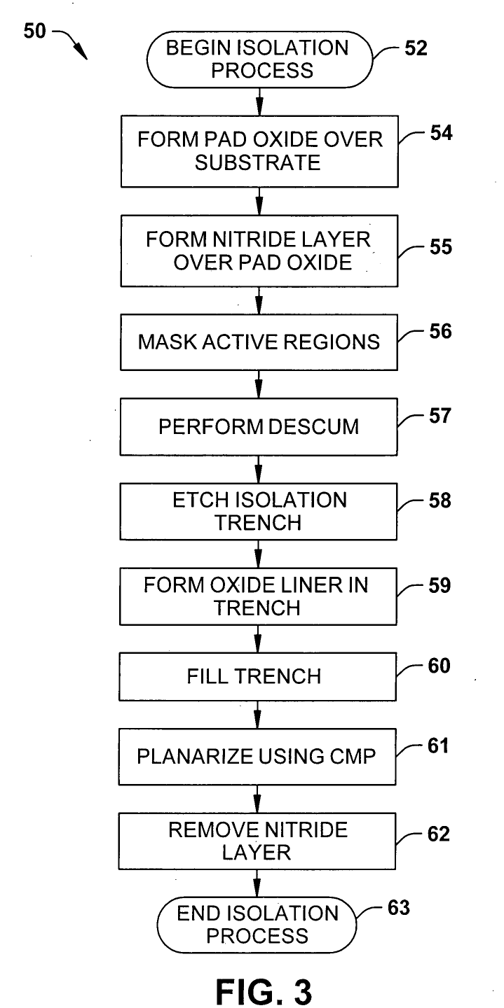

FIG. 3 is a flow chart illustrating a method 50 of forming a shallow trench isolation structure according to one aspect of the present invention. Although the method 50 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the devices and systems illustrated and described herein as well as in association with other structures not illustrated.

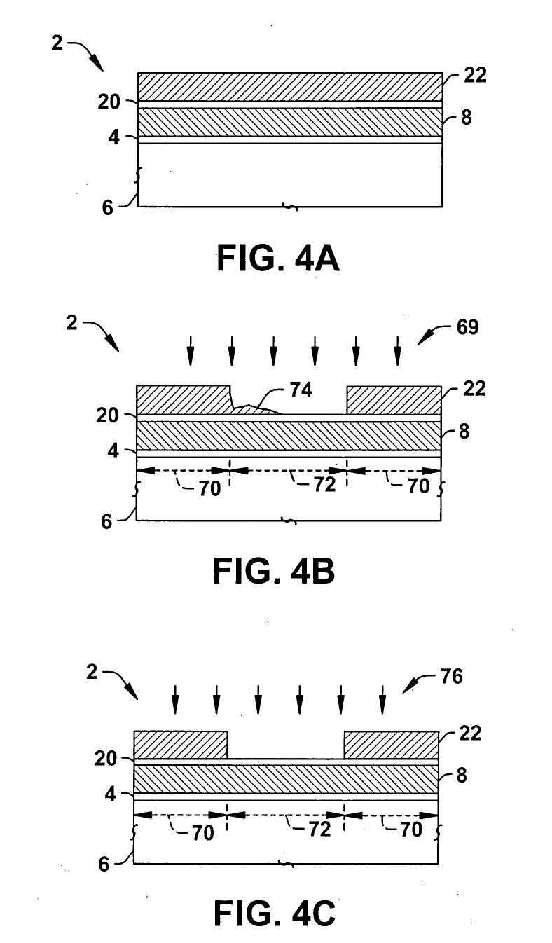

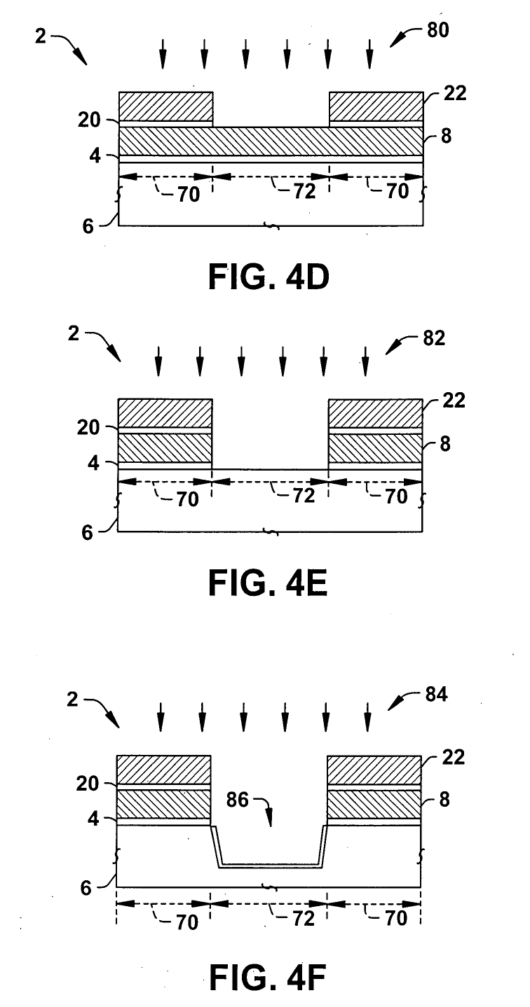

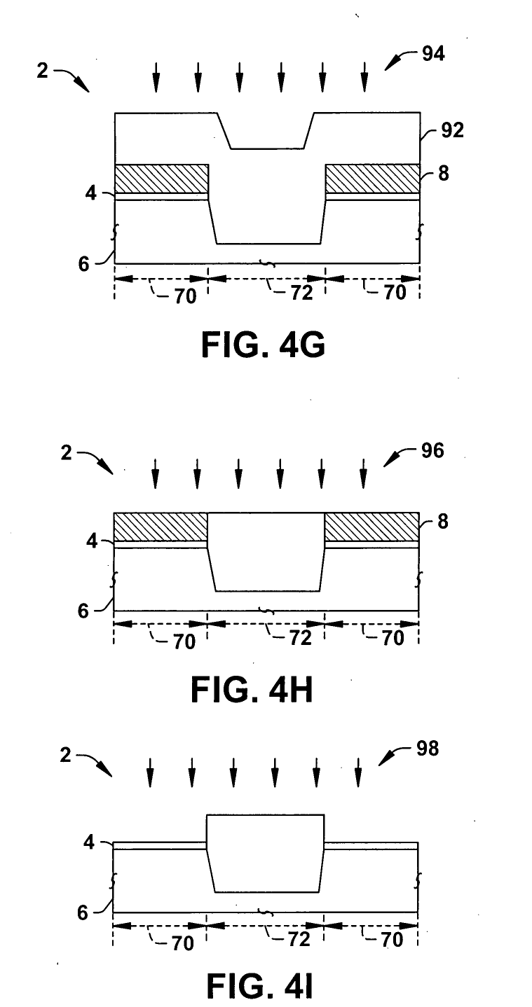

The method 50 begins at 52, and a pad oxide 4 is formed over the substrate 6 at 54, followed by the formation of a nitride layer 8 thereover at 55, as illustrated in FIG. 4A. In one embodiment of the invention the pad oxide 4 and nitride layer 8 are formed, however, more generally, any base buffer layer may be employed (a single or multi-layer), wherein the base buffer layer serves to protect the active regions of the substrate 6 from subsequent processing in the method 50, as will be appreciated infra.

The method 50 proceeds at 56 of FIG. 3, wherein a mask layer 20, 22 is formed, as illustrated in FIG. 4A over the nitride layer 8, and then patterned 69 to mask active regions 70 of the substrate and defining a trench region 72, as illustrated in FIG. 4B. In one embodiment of the invention, the mask layer is a bi-layer film comprising an anti-reflective coating 20 and a photoresist layer 22 thereover. The anti-reflective coating 20, in one embodiment, serves to reduce reflections in the overlying photoresist layer 22 during a selective exposure thereof with radiation during lithographic processing. In the above manner, the anti-reflective coating 20 serves to maintain small critical dimensions relating to the trench region 72.

As can be seen in FIG. 4B, the patterning 69 of the photoresist 22, for example, via development thereof, may result in a small amount of particulate matter 74 in the trench region 72. In one embodiment, the matter 74 may be a portion of the photoresist layer 22 that was not fully removed, due to the continuing reduction in the critical dimension size of the trench opening. Alternatively, the matter 74 may be any type of particulate contamination. As may be appreciated, while a photoresist 22 and anti-reflective coating 20 are disclosed in one exemplary embodiment of the invention, it should be appreciated that any masking layer may be employed, and all such alternatives are contemplated as falling within the scope of the present invention.

Returning to FIG. 3, a descum operation is then performed at 57 to remove the particulate matter 74 in the trench region 72, as illustrated in FIG. 4C at 76. Any form of wet or dry clean process may be employed to remove the particulate matter 74, and all such descum operations are contemplated as falling within the scope of the invention. In one embodiment, the descum operation 57 comprises a dry plasma etch employing a reactive species that serves to remove the particulate matter 74 without substantially impacting the desired critical dimension of the trench opening 72.

More particularly, in one embodiment of the invention, the descum operation 57 comprises an oxygen based plasma. In a further embodiment, the descum operation 57 comprises an oxygen based plasma with an RF bias of 50 W, a chamber pressure of 30 mT, an argon flow of 15 sccm, and an oxygen flow of 15 sccm. Further, in such a plasma operation, the substrate may be biased, wherein the potential thereat creates an electrostatic field that causes the oxygen ions to be directed downward toward the substrate in a substantially vertical manner. Further, the argon ions thereon help to create a physically aspect of the descum operation as opposed to solely a chemical nature, wherein the particulate matter 74 is chemically reacted with by the reactive species (e.g., oxygen ions), in addition to being physically reacted with by the kinetic energy imparted to the downward ions (e.g., oxygen and argon ions). In the above manner, the descum operation operated preferentially in the vertical direction to remove the particulate matter 74 without substantially affecting the sidewalls of the mask layer 22, thereby maintaining the integrity of the critical dimension of the trench opening 72.

While one or more examples are provided above for the descum operation 57, it should be understood that other reactants may be employed to remove the particulate matter 74 at this stage of the process 50, and any such alternatives are contemplated as falling within the scope of the invention.

The method 50 continues at 58 of FIG. 3, wherein an isolation trench is patterned, for example, by etching. In one embodiment of the invention, this patterning at 58 comprising a dry etch 80 of the anti-reflective coating 20, following by a dry etch 82 of the underlying nitride 8 and pad oxide 4 in that order, as illustrated in FIGS. 4D and 4E, respectively. Differing dry etch chemistries may be employed as desired. Act 58 continues with an etch 84 (e.g., a dry etch) of the substrate 6 to form the isolation trench 86, as illustrated in FIG. 4F. An oxide liner 90 is then formed in the trench 86, in one embodiment, at 59 using, for example, a thermal oxidation process. This optional act 59 may be employed to remedy etch damage in the substrate 6 and to provide, in some instances, some corner rounding at bottom portions of the trench.

Referring to FIG. 3, a trench fill occurs at 60, for example, by a chemical vapor deposition 94 of a dielectric material 92 such as silicon dioxide, as illustrated in FIG. 4G in one embodiment. As shown, the dielectric fill material 92 is generally conformal, thereby resulting in a non-planar top surface. A planarization process 61 is then performed to planarize the top surface of the dielectric fill material 92. In one embodiment of the invention, the planarization 68 comprises a chemical mechanical polishing (CMP) 96, wherein the CMP stops on the nitride layer 8, as illustrated in FIG. 4H.

The nitride layer 8 is then removed at 62, at which point the isolation processing ends at 63. In one embodiment, the nitride layer 8 is removed by a dry etch process 98, as illustrated in FIG. 4I. The resultant isolation structure 100 therefore fills the trench region 72 and exhibits a step height that reaches above the surface of the body an amount that is roughly equal to the removed nitride layer 8.

Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of forming a shallow trench isolation structure, comprising:
forming a mask structure over active regions of a substrate, thereby defining a trench region therebetween;
performing a descum to remove any particulate matter that may be in the trench region over the substrate; and
forming a trench in the substrate corresponding to the trench region of the mask structure.

2. The method of claim 1, wherein forming the mask structure comprises:
forming a nitride layer over the substrate;
forming a photoresist layer over the nitride layer; and
selectively removing a portion of the photoresist layer to define the trench region.

3. The method of claim 2, further comprising patterning the nitride layer using the photoresist layer as an etch mask to define the trench region in the patterned nitride layer.

4. The method of claim 2, further comprising forming an anti-reflective coating over the nitride layer and before forming the photoresist layer.

5. The method of claim 1, wherein performing the descum comprises subjecting the mask structure and the trench region with an etchant, thereby removing the particulate matter from the trench region.

6. The method of claim 5, wherein the etchant comprises an oxygen based plasma.

7. The method of claim 6, further comprising biasing the substrate, thereby directing oxygen ions in the oxygen based plasma substantially vertically toward the substrate.

8. The method of claim 1, further comprising filling the trench with an electrically insulating material.

9. A method of forming a shallow trench isolation structure, comprising:
forming a base buffer layer over the substrate;
forming a mask layer over the base buffer layer;
patterning the mask layer to form an opening therein defining a trench region thereat and active regions elsewhere;
performing a descum operation to remove any particulate matter in the mask layer opening;
patterning the base buffer layer and the substrate through the mask layer opening, thereby forming a trench in the substrate.

10. The method of claim 9, wherein the base buffer layer comprises a silicon nitride layer.

11. The method of claim 10, wherein the base buffer layer further comprises a pad oxide layer interposed between the silicon nitride layer and the substrate.

12. The method of claim 9, wherein forming the mask layer comprises depositing a photoresist layer.

13. The method of claim 12, wherein patterning the mask layer comprises:
subjecting a portion of the photoresist layer associated with the opening to radiation; and
subjecting the photoresist layer to a developer, thereby removing the portion of the photoresist layer associated with the opening.

14. The method of claim 13, further comprising:
forming an anti-reflective coating over the base buffer layer prior to forming the mask layer; and
patterning the anti-reflective coating using the patterned mask layer after the descum operation.

15. The method of claim 9, wherein performing the descum operation comprises subjecting the patterned mask layer to an etchant, thereby removing any particulate matter from the opening.

16. The method of claim 15, wherein the etchant comprises an oxygen based plasma.

17. The method of claim 16, further comprising biasing the substrate, thereby directing oxygen ions in the oxygen based plasma substantially vertically toward the substrate.

18. The method of claim 9, further comprising filling the trench with an electrically insulating material.

19. A method of forming a shallow trench isolation structure, comprising:
forming a patterned etch mask over the substrate, the patterned etch mask defining a trench opening;
performing a descum operation after forming the patterned etch mask, thereby removing any particulate matter from the trench opening;
forming a trench corresponding to the trench opening in the substrate; and
filling the trench with an electrically isolating material.

20. The method of claim 19, wherein the patterned etch mask comprises a developed photoresist, and further comprising forming a nitride layer over the substrate prior to forming the patterned etch mask.

21. The method of claim 19, wherein performing the descum operation comprises subjecting the patterned etch mask to an oxygen based plasma.

22. The method of claim 21, further comprising applying a bias to the substrate, thereby directing oxygen ions in the oxygen based plasma down toward the substrate in a generally vertical direction.
